(19) United States
(12) Patent Application Publication
(10) Pub. No.: US 2009/0191349 A1
(43) Pub. Date: Jul. 30, 2009

(54) AEROSOL GENERATOR, METHOD FOR GENERATING AEROSOL, FILM FORMING APPARATUS, AND METHOD FOR MANUFACTURING FILM FORMING BODY

(75) Inventor: Takahiro NORIMATSU, Hekinan-shi (JP)

Correspondence Address: BAKER BOTTS LLP;C/O INTELLECTUAL PROPERTY DEPARTMENT, THE WARNER, SUITE 1300, 1299 PENNSYLVANIA AVE, NW, WASHINGTON, DC, 20004-2400, US

(73) Assignee: BROTHER KOGYO KABUSHIKI KAISHA, Nagoya-shi (JP)

(21) Appl. No.: 12/363,503

(22) Filed: Jan. 30, 2009

(30) Foreign Application Priority Data
Jan. 30, 2008 (JP) 2008-019097

(51) Int. Cl. B05D 1/02; C23C 16/54

(52) U.S. Cl. 427/421.1; 118/722

(57) ABSTRACT

An aerosol generator includes a generator vessel in which a powder of material particles is accommodated, a jetting port which jets a gas, in a direction having a component in a circumferential direction with a substantial center of an inner circumference of the generator vessel as a center of a circle, into the powder of the material particles which are accommodated and accumulated in the generator vessel, a first gas supply mechanism which supplies a gas to the jetting port; and a controller which controls the first gas supply mechanism to adjust supply amount of the gas to the jetting port.

### CROSS REFERENCE TO RELATED APPLICATION

The present application claims priority from Japanese Patent Application No. 2008-019097, filed on Jan. 30, 2008, the disclosure of which is incorporated herein by reference in its entirety.

### BACKGROUND OF THE INVENTION

1. Field of the Invention

The present invention relates to a technology for generating aerosol which is used at the time of manufacturing a film forming body by an aerosol deposition method (hereinafter, “AD method”).

2. Description of the Related Art

An aerosol deposition method is a technology in which material particles which are transformed into aerosol by mixing with a carrier gas are guided into a depressurized space inside a film forming chamber, and based on a pressure difference between an internal pressure of the film forming chamber and an internal pressure of a nozzle, the aerosol is jetted at a high speed from the nozzle onto a substrate, and a film of the material particles is formed on the substrate. A film forming apparatus for carrying out such AD method is provided with an aerosol generator which generates aerosol in which the material particles are mixed and dispersed in a carrier gas. The aerosol generator, in general, includes a generator vessel in which a powder including material particles (hereinafter, “material powder”) is loaded, and a gas infusing mechanism which infuses the carrier gas into the generator vessel to blow up the material powder.

Incidentally, in the abovementioned aerosol generator, aggregation of the material particles in the generator vessel due to a use for a long period has hitherto been a problem. An aggregate of the material powder (hereinafter, “aggregate of material particles”) which is hardened by aggregating of the material particles is susceptible to be accumulated at a lower layer portion of the material powder accumulated in the generator vessel. Therefore, the material particles at the lower layer portion of the material powder accumulated in the generator vessel are hardly dispersed in the carrier gas and a suitable stirring and fluidization of the material powder by the carrier gas is inhibited, and fluidity of the material powder is declined.

As it has been described above, in the aerosol generator, in a course of using for a long period of time, since the material particles at the lower layer portion of the material powder accumulated in the generator vessel cannot be transformed into aerosol, it is difficult to maintain a concentration of material particles in the aerosol generator to be constant over a long period of time. When the concentration of the material particles in the aerosol declines, there is an adverse effect such as, a decline in a speed of film forming and a non-uniform thickness of a film which is formed. Consequently, maintaining the concentration of the material particles in aerosol to be constant over a long period of time for securing a stability of the film formation has been a vital issue for putting the film forming apparatus in which the AD method is used to a practical use. In view of this, as it has been described in Japanese Patent Application Laid-open Nos. 2004-113931 and 2007-186737, a technology for maintaining the concentration of aerosol generated in the aerosol generator to be constant has been proposed.

An aerosol generator described in Japanese Patent Application Laid-open No. 2004-113931 includes a generator vessel having a material powder placed inside, a gas infusing mechanism which generates aerosol by spouting the material powder, a stirrer which stirs the material powder, a shaking mechanism which imparts minutes vibrations to the generator vessel, and a driving mechanism which drives the generator vessel such that the generator vessel undergoes a rotational motion or a pendulum motion. Moreover, by imparting minute vibrations and a predetermined motion to the generator vessel, the aggregate of the material particles is prevented from being accumulated at one location in the generator vessel.

Moreover, an aerosol generator described in Japanese Patent Application Laid-open Publication No. 2007-186737 includes a generator vessel which accommodates the material powder, a stirrer which moves with a lower portion buried in the material powder accommodated in the generator vessel, and a blow-off port of carrier gas which is open toward the stirrer at an upper side of the material powder in the generator vessel. A strong vortex is developed due to a flow of the carrier gas at a downstream side of the stirrer, and the material particles stirred by a movement of the stirrer being involved in the vortex are dispersed, and aerosol is generated. By stirring the material powder by the stirrer in such aerosol generator, the coagulation and solidification of the material particles are prevented.

In the aerosol generator described in Japanese Patent Application Laid-open No. 2004-113931, a structure in which an area near a jetting port of the carrier gas infusing portion is curved along a circumference, and the carrier gas is made to be jetted in a tangential direction has been disclosed (FIG. 1 and paragraph no. 0016). This carrier gas is for blowing up the material powder, and the aerosol generator is provided with the driving mechanism and the shaking mechanism for preventing the aggregation of the material particles.

However, a fact that the structure of the aerosol generator is simple is useful from a point of cost and maintenance. In other words, it is desirable that the aerosol generator has a structure which does not include complicated mechanical mechanism such as the shaking mechanism and the driving mechanism of the generator vessel, and the stirrer of the material powder. Therefore, preventing the aggregation of the material particles by making collide the aggregates of the material particles by continuously infusing at a high speed a gas corresponding to the carrier gas into the generator vessel may be taken into consideration. However, in this case, since a flow of the gas infused into the generator vessel becomes substantial, a cost for supplying the gas becomes extremely high. Furthermore, when a gas infusing port is formed in a material powder of which the fluidity is declined due to the generation of an aggregate of the material particles, a cavity in the form of a tunnel along a flow of the gas is developed near the infusing port and the aggregate of the material particles is accumulated around the cavity, and as a result, an appropriate flow of the material powder is not achieved.

### SUMMARY OF THE INVENTION

The present invention is made in view of the abovementioned issues, and an object of the present invention is to propose a technology to carry out efficiently cracking of an aggregate of the material particles and stirring of a material powder by infusing a gas into a generator vessel, in an aerosol generator which generates aerosol by dispersing the material particles in a carrier gas.

According to a first aspect of the present invention, there is provided an aerosol generator which generates aerosol by dispersing material particles in a carrier gas, including: a generator vessel in which a powder of material particles is accommodated; a jetting port which jets a jetting gas, in a direction having a component in a circumferential direction with a substantial center of an inner circumference of the generator vessel as a center of a circle, into the powder of the material particles accommodated and accumulated in the generator vessel; a first gas supply mechanism which supplies the jetting gas to the jetting port; and a controller which controls the first gas supply mechanism to adjust supply amount of the jetting gas supplied to the jetting port. In the aerosol generator of the present invention, the controller may control the first gas supply mechanism to supply the jetting gas intermittently to the jetting port.

In the aerosol generator, by the gas at a high speed being jetted intermittently into the powder of the material particles accumulated in the generator vessel, cracking of an aggregate of the material particles, and stirring of the powder of the material particles are carried out efficiently. Due to the cracking of the aggregate of the material particles and the stirring of the powder of the material particles, an appropriate fluidity of the powder of the material particles is maintained, and the generation of aggregates of the material particles is prevented. Moreover, it is possible not only to generate aerosol with a constant concentration of the material particles in the aerosol generator over a long period of time, but also to carry out film formation with stable conditions in a film forming apparatus which carries out an AD method.

In the aerosol generator of the present invention, the jetting port may be formed as a plurality of jetting ports, and the jetting ports may be grouped into a plurality of port groups each including at least one jetting port; and the controller may control the first gas supply mechanism to supply the jetting gas to each of the jetting ports, and to jet the jetting gas with a same phase from the jetting ports belonging to a group among the port groups, and to jet the jetting gas with different phases from jetting ports belonging to different groups respectively, among the port groups.

In the aerosol generator of the present invention, the controller may control the first gas supply mechanism to supply the jetting gas to each of the jetting ports, and to jet the jetting gas such that at least a part of a jetting period of one group does not overlap with a jetting period of remaining groups among the plurality of port groups and that there is no period which is not a jetting period of any groups among the port groups. The controller may control the first gas supply mechanism to supply the jetting gas to each of the jetting ports, and to jet the jetting gas such that a total flow of the jetting gas jetted from the jetting ports belonging to a certain group among the port groups is same as a total flow of the jetting gas jetted from the jetting ports belonging to remaining groups among the port groups.

In the aerosol generator of the present invention, the jetting port may be an opening provided at a tip of a jetting nozzle; and the first gas supply mechanism may include a gas supply source, a gas supply passage through which the jetting gas is fed from the gas supply source to the jetting nozzle, and a flow adjuster which is provided on the gas supply passage and which adjusts the supply amount of the jetting gas to be supplied to the jetting port.

In the aerosol generator of the present invention, the jetting port may be formed as a plurality of jetting ports, and the jetting ports may be formed to be away from each other in a circumferential direction of an inner circumference of the generator vessel. Moreover, the jetting ports may be formed to be away from each other at an equiangular distance in the circumferential direction of the inner circumference of the generator vessel. Furthermore, the jetting ports maybe formed on an inner wall surface of the generator vessel.

In the aerosol generator of the present invention, the generator vessel may have a cylindrical shape and the jetting ports may be formed at positions which are same distance from a bottom of the generator vessel. Further, the positions at which the ports are formed may be positioned lower than a height of the material particles accumulated in the generator vessel.

In the aerosol generator of the present invention, the generator vessel may include a porous plate which divides an internal space of the generator vessel into an aerosol generation chamber accommodating the powder of the material particles and a fluid gas introducing chamber which is positioned below the aerosol generation chamber, and a second gas supply mechanism which supplies the fluid gas to the fluid gas infusing chamber.

According to a second aspect of the present invention, there is provided a method for generating aerosol by dispersing material particles in a carrier gas by using the aerosol generator as defined in the first aspect of the present invention, the method including: accommodating a powder of material particles in the generator vessel; and jetting a jetting gas intermittently from the jetting port.

According to a third aspect of the present invention, there is provided a film forming apparatus including: the aerosol generator as defined in the first aspect of the present invention; and a depressurizing vessel including a stage which holds a film forming body, and an aerosol jetting nozzle which jets aerosol generated in the aerosol generator onto the film forming body held by the stage, the stage and the aerosol jetting nozzle being arranged in the depressurizing vessel.

According to a fourth aspect of the present invention, there is provided a method for manufacturing a film forming body by using the film forming apparatus as defined in the third aspect of the present invention, the method including: generating aerosol in the aerosol generator; introducing the aerosol into the depressurizing vessel; and jetting the aerosol introduced into the depressurizing vessel from the aerosol jetting nozzle arranged in the depressurizing vessel onto the film forming body placed in the depressurizing vessel.

### BRIEF DESCRIPTION OF THE DRAWINGS

FIG. 1 is a diagram showing an overall structure of a film forming apparatus according to a first embodiment of the present invention;

FIG. 2 is a side view of an aerosol generator according to the first embodiment;

FIG. 3 is an end-face cross-sectional view taken along a line III-III in FIG. 2 of a nozzle block;

FIG. 4 is diagram showing a schematic structure of jetting nozzles and a gas pipeline connected to the jetting nozzles according to the first embodiment;

FIG. 5 is a diagram showing a time change of a jetting gas flow into a generator vessel;

FIG. 6 is a flowchart of manufacturing a film forming body in which a film forming apparatus is used;

FIG. 7 is a side view of an aerosol generator according to a second embodiment of the present invention; and

FIG. 8 is a front cross-sectional view taken along a line VIII-VIII in FIG. 7.

### DETAILED DESCRIPTION OF THE PREFERRED EMBODIMENTS

A first embodiment of the present invention will be described below.

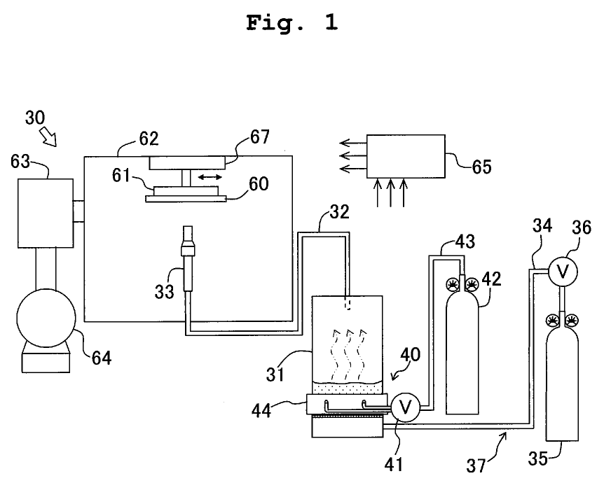

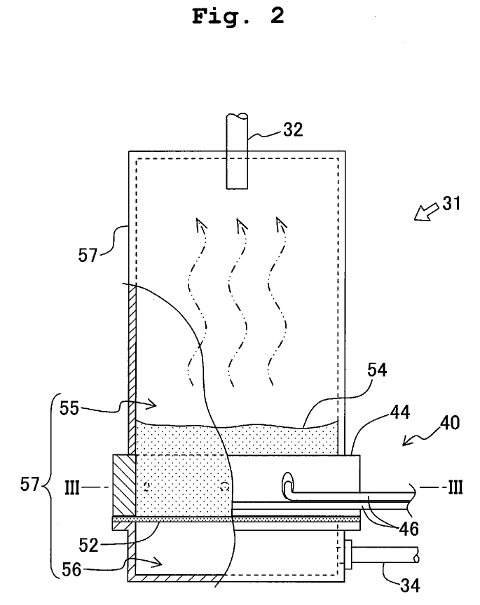

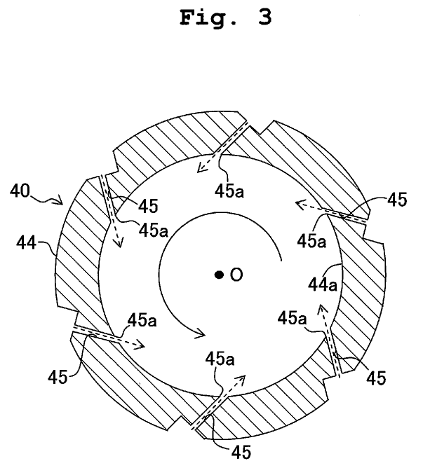

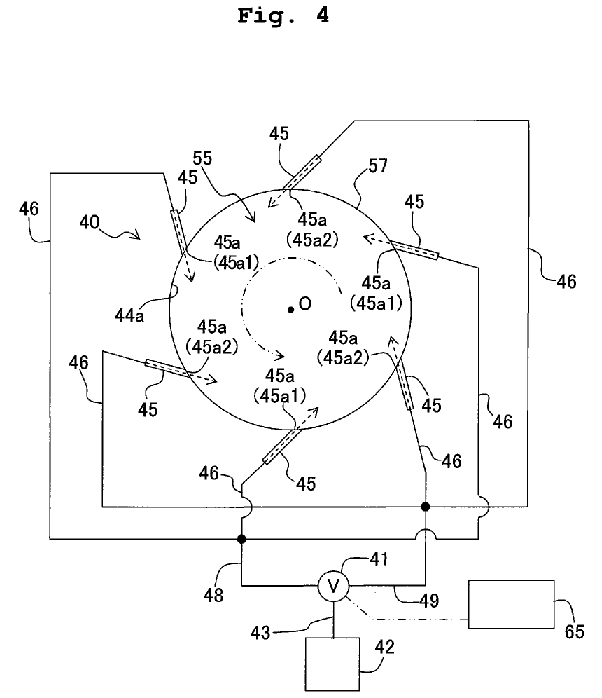

First of all, a structure of an aerosol generator 31 will be described below by using diagrams from FIG. 1 to FIG. 5. FIG. 1 shows a diagram of an overall structure of a film forming apparatus according to the first embodiment. FIG. 2 is a side view of an aerosol generator according to the first embodiment. FIG. 3 is an end-face cross-sectional view taken along a line III-III in FIG. 2 of a nozzle block. FIG. 4 is a diagram showing a schematic structure of jetting nozzles and a gas pipeline connected to the jetting nozzles according to the first embodiment. FIG. 5 is a diagram showing a time change of a jetting gas flow into a generator vessel.

As shown in FIG. 1 and FIG. 2, the aerosol generator 31 includes a generator vessel 57 being a cylindrical shape in which a powder including material particles (hereinafter, “material powder”) is accommodated, a jetting gas supply mechanism 40 which supplies a gas at a high speed which is jetted into the material powder accumulated inside the generator vessel 57 (hereinafter, “jetting gas”), and a fluid gas supply mechanism 37 which supplies a gas which fluidizes the material powder accumulated inside the generator vessel 57 (hereinafter, “fluid gas”). The jetting gas and the fluid gas together carry the material particles which are dispersed, and become a carrier gas of aerosol. In the present invention, various gases are called as “a jetting gas”, “a fluid gas”, and “a carrier gas” based on a function of each gas as described above,

The material particles is a material which can be used in a film forming process according to an AD method, and are particles of a particle diameter (in a range of several hundreds of nm to several tens of μm) which can be used in a film forming process according to the AD method. An inorganic powder of a material such as alumina and lead zirconate titanate which is a piezoelectric material can be used as such material particles. Moreover, the jetting gas and the fluid gas are gases which can be used as a carrier gas of aerosol used in the film forming process according to the AD method, and it is possible to use an inert gas such as helium and argon, and a gas such as air, oxygen, and nitrogen.

A porous plate 52 is provided in the generator vessel 57 to divide an internal space into two chambers namely an upper space and a lower space. The porous plate 52 is a member in the form of a sheet or a plate provided with fine holes of about a size through which a fluid gas passes but the material particles do not pass, such as a mesh plate provided with a fine mesh or a punching metal in which a large number of fine holes are formed.

Out of the internal spaces of the generator vessel 57, the upper space separated by the porous plate 52 functions as an aerosol generation chamber 55 which generates aerosol in which the material particles are dispersed in a carrier gas. An aerosol supply tube 32 which supplies aerosol to an inside of a film forming chamber 62 of a film forming apparatus 30 which will be described later is connected to a ceiling surface of the aerosol generation chamber 55, in other words, to a ceiling surface of the generator vessel 57. A bottom surface of the aerosol generation chamber 55 is formed by the porous plate 52, and the material powder is accommodated in the aerosol generation chamber 55 in the form of being accumulated on the porous plate 52.

Furthermore, a plurality of jetting ports 45a each of which jets a jetting gas (through which a jetting gas is jetted) are formed in the aerosol generation chamber 55, and these jetting ports 45a open in the material powder accumulated inside the aerosol generation chamber 55. In the first embodiment, the jetting port 45a is a port formed at a front end of a jetting nozzle 45. A diameter of the jetting port 45a is determined according to an overall flow of the jetting gas. In other words, in a case of increasing the total flow of the jetting gas, the diameter may be formed to be large, and in a case of decreasing the total flow of the jetting gas, the diameter may be formed to be small.

On the other hand, the lower space separated by the porous plate 52 functions as a fluid gas infusing chamber 56 for infusing a fluid gas into the generator vessel 57. The fluid gas which is supplied to the fluid gas infusing chamber 56 passes through the minute holes in the porous plate 52 from the fluid gas infusing chamber 56, and is flowed into the material powder accumulated on a bottom portion of the generator vessel 57. The fluid gas which flows into the aerosol generation chamber 55 from the fluid gas infusing chamber 56 blows the material powder accumulated on the bottom portion of the generator vessel 57 in a state in which it can flow just like a fluid. An accumulated layer of the material powder which can flow like a fluid is called as a “fluid layer 54”.

Moreover, the fluid gas which flows from the fluid gas infusing chamber 56 into the aerosol generation chamber 55 blows up the material particles in the material powder accumulated on the bottom portion of the aerosol generation chamber 55. Further, the fluid gas becomes a carrier gas carrying the material particles blown in the aerosol generation chamber 55, and aerosol in which the material particles are dispersed in the carrier gas is generated.

The fluid gas supply mechanism 37 includes a fluid gas supply source 35, a fluid glass supply tube 34 which forms a gas supply passage from the fluid gas supply source 35 to the generator vessel 57, and a flow controller 36 which is provided to the fluid gas supply tube 34, and which adjusts an amount of the fluid gas to be supplied to the generator vessel 57. One end of the fluid gas supply tube 34 is connected to a wall surface which communicates with the fluid gas infusing chamber 56 of the generator vessel 57. According to such structure, the fluid gas with the flow adjusted is supplied from the fluid gas supply source 35 to the fluid gas infusing chamber 56 via the fluid gas supply tube 34.

Moreover, the jetting gas supply mechanism 40 includes a jetting gas supply source 42, a jetting gas infusing tube 46, and a jetting gas supply tube 43 which form a gas supply passage sending the jetting gas from the jetting gas supply source 42 to the jetting nozzles 45, and a flow controller 41 which is provided between the jetting gas supply tube 43 and the jetting gas infusing tube 46, and which controls a flow of the jetting gas to be supplied to each jetting port 45a. In the first embodiment, the jetting gas supply source 42 is provided separately from the fluid gas supply source 35. However, one gas supply source may serve the purpose.

As shown in FIG. 2 and FIG. 3, the plurality of jetting nozzles 45 is formed in one nozzle block 44. The nozzle block 44 is a circular cylindrical shaped body which is provided integrally to the generator vessel 57, and an inner surface 44a of a circumferential wall of the nozzle block 44 forms a part of an inner wall of the aerosol generation chamber 55. Six jetting nozzles 45 are formed in a thickness of the peripheral wall of the nozzle block 44, and the jetting ports 45a of the jetting nozzles 45 appear in the inner wall 44a of the same peripheral wall. Here, the inner surface 44a of the peripheral wall of the nozzle block 44 also being an inner wall surface of the generator vessel 57, the plurality of jetting ports 45a is formed in the inner wall surface of the generator vessel 57. In this manner, when the jetting ports 45a are formed in the inner wall surface of the generator vessel 57, since the jetting nozzle 45 does not become an obstacle for a flow of the material powder, it is preferable for maintaining an appropriate flow of a fluid layer of the material powder. It is desirable that the number of jetting nozzles 45 is for example 6 to 8, when the inner diameter of the generator vessel 57 is approximately 60 mm to 80 mm. The jetting nozzles 45 may be formed parallel to the bottom surface of the generator vessel 57 or may be inclined upwardly or downwardly.

The jetting ports 45a are arranged to be separated away in a circumferential direction of an inner circumference of the generator vessel 57 (here, nozzle block 44) in a plan view. In this case, it desirable that the jetting ports 45a are at an equiangular distance (in other words, at a same distance in the circumferential direction) with a substantial center of the inner circumference of the generator vessel 57 as a center O of a circle in a plan view. Moreover, a direction of jetting of a gas jetted from each jetting port 45a is inclined in a clockwise direction at the same angle with respect to a radial direction of the inner circumference of the generator vessel 57, and has a component in a circumferential direction having the substantial center of the inner circumference of the generator vessel 57 as a center O of a circle.

The jetting gas is supplied intermittently to each jetting port 45a, and is jetted intermittently at a high speed from each jetting port 45a. The plurality of jetting ports 45a is divided into a plurality of groups according to a phase jetted by the jetting gas. One group includes one jetting port or a plurality of jetting ports jetting the jetting gas at the same phase. Moreover, the jetting gas is supplied to each jetting port by the jetting gas supply mechanism 40 such that the jetting gas is jetted at different phases from the jetting ports belonging to the mutually different groups. In this case, it is desirable to make an arrangement such that, a jetting period does not overlap in the plurality of groups, and that there is no period which is not a jetting period for any of the groups. Furthermore, it is desirable that for any of the groups, a total flow of the jetting gas jetted from the jetting ports belonging to that group is substantially the same.

In the first embodiment, the six jetting ports 45a are divided into two groups of three jetting ports each namely a first group and a second group according to the phase of jetting of the jetting gas. As shown in FIG. 4, each of jetting ports 45a₁ belonging to the first group is adjacent to jetting ports 45a₂ belonging to the second group. In other words, the jetting ports 45a₁ belonging to the first group and the jetting ports 45a₂ belonging to the second group are arranged alternately in the circumferential direction of the generator vessel 57.

Moreover, as shown in FIG. 5, the jetting gas is supplied to each jetting port 45a by the jetting gas supply mechanism 40 such that the total flow of the jetting gas from the jetting ports belonging to each of the first group and the second group is substantially the same, and jetting from the jetting ports 45a₁ belonging to the first group and jetting from the jetting ports 45a₂ belonging to the second group are continuously carried out alternately. By the amount of the jetting gas supplied to each jetting port 45a being controlled in such manner, even when the jetting of the jetting gas from the jetting ports 45a₁ belonging to the first group and the jetting of the jetting gas from the jetting ports 45a₂ belonging to the second group is carried out alternately, the flow of the jetting gas supplied into the generator vessel 57 becomes substantially constant, and it is possible to suppress a pressure fluctuation inside the generator vessel 57. Moreover, by suppressing the pressure fluctuation inside the generator vessel 57, since it is possible to suppress a pulsation of pressure and a concentration of aerosol which is supplied to the film forming chamber 62, it is possible to carry out the film formation at a stable speed of film forming. By grouping all the jetting ports 45a into the first group and the second group and jetting from the first group and the second group alternately, it is possible to increase jetting amount from each jetting port 45a as compared with a case in which a constant amount of the jetting gas is always jetted from all the jetting ports 45a. In this case, it is preferable that each of the jetting time T1 and the stop time T2 per one jetting of the jetting gas from the jetting ports 45a₁ belonging to the first group is not shorter than one second. Similarly, it is preferable that each of the jetting time T3 and the stop time T4 per one jetting of the jetting gas from the jetting ports 45a₂ belonging to the second group is not shorter than one second. If each of T1, T2, T3, and T4 is shorter than one second, as it will be described later, a tunnel shaped cavity which is developed near the jetting port 45a by jetting gas jetted from the jetting port 45a is hardly broken. Accordingly, the aggregate of the material powder accumulates around the cavity, and it is not possible to obtain an effect of stirring sufficiently. In a case of FIG. 5, the jetting from the jetting ports 45a₁ belonging to the first group and the jetting from the jetting ports 45a₂ belonging to the second group do not overlap at all. However, the jetting from the jetting ports of the respective groups may overlap partially. For instance, in a case in which the change in the flow is as a sine curve and not a substantially rectangular shaped as in FIG. 5, it is favorable to make an arrangement such that, the flow of the two groups overlap when the flow is not the maximum flow, and that when the flow is the maximum in one group, there is no jetting from the other group.

A structure of the jetting gas supply mechanism which is capable of controlling the amount of the jetting gas supplied to each jetting port 45a as described above is as follows.

An infusing port of each jetting nozzle 45 appears on an outer peripheral surface of the nozzle block 44, and the jetting gas infusing tube 46 is connected to the infusing port of the jetting nozzle 45. The jetting gas infusing tubes 46 connected to the jetting ports 45a₁ belonging to the first group are one first-group jetting gas infusing tube 48 branched into three, and the first-group jetting gas infusing tube 48 is connected to the flow controller 41. On the other hand, the jetting gas infusing tubes 46 connected to the jetting ports 45a₂ belonging to the second group are one second-group jetting gas infusing tube 49 branched into three, and the second-group jetting gas infusing tube 49 is connected to the flow controller 41.

The flow controller 41 is a controller which functions as a flow controlling mechanism and a channel switching mechanism of the jetting gas which is sent from the jetting gas supply source 42 via the jetting gas supply tube 43. An operation of the flow controller 41 is controlled by a controller 65 which will be described later, the controller 65 controls the operation of the flow controller 41 such that when the aerosol generator 31 is stopped, no jetting gas is sent to any of the first-group jetting gas infusing tube 48 and the second-group jetting gas infusing tube 49. On the other hand, the controller 65 controls the operation of the flow controller 41 to switch alternately to either a state in which the jetting gas is sent only to the first-group jetting gas infusing tube 48 or a state in which the jetting gas is sent only to the second-group jetting gas infusing tube 49 when the aerosol generator 31 is in operation. A rotary valve for example, can be used as such flow controller 41.

In the aerosol generator 31 having the abovementioned structure, when the state is switched alternately to either the state in which the jetting gas is sent only to the first-group jetting gas infusing tube 48 or the state in which the jetting gas is sent only to the second-group jetting gas infusing tube 49, the jetting of the jetting gas at a high speed from the jetting ports 45a₁ belonging to the first group and the jetting of the jetting gas at a high speed from the jetting ports 45a₂ belonging to the second group are repeated alternately at a timing shown in FIG. 5.

As it has been described above, by blowing of the high speed jetting gas from the jetting port 45a into the fluid layer 54 of the material powder, due to a collision of aggregates of the material particles, a collision of the material particles, or a collision of the aggregates of the material particles with the material particles, cracking of the aggregates of the material particles and a crushing of the material particles (in other words, crushing of the material particles to fragments) occurs. When a jetting pressure of the jetting gas is lowered appropriately, it is possible to carry out the cracking of the aggregates of the material particles. Moreover, when a jetting pressure of the jetting gas is increased appropriately, it is possible to carry out both the cracking of the aggregates of the material particles and the crushing of the material particles. Furthermore, the fluid layer 54 is stirred by the jetting gas jetted into the fluid layer 54. Accordingly, it is possible to suppress the aggregation of the material particles.

Moreover, by jetting intermittently the jetting gas from each jetting port 45a, it is possible to increase the maximum flow velocity of the jetting gas as compared to jetting continuously the jetting gas at the same jetting gas flow. Furthermore, since the jetting pressure of the jetting gas on the material powder at the same location in the generator vessel 57 changes pulsatingly, even when a tunnel shaped cavity along the flow of the gas is developed near the jetting port 45a while the jetting gas is jetted from the jetting port 45a, the cavity is broken by a deadweight of the material powder while the gas is stopped. Consequently, the aggregate of the material powder hardly accumulates around the cavity as it used to be conventionally, and it is possible to carry out more effective cracking, crushing, and stirring by even smaller flow of the jetting gas.

By the effect of stirring the fluid layer 54, the effect of crushing the material particles, and the effect of cracking the aggregates of the material particles due to the jetting gas in such manner, it is possible to generate stably the aerosol over a long period of time by the aerosol generator 31. In other words, it becomes possible to keep constant the concentration of the material particles in aerosol over a long period of time.

Next, a structure of the film forming apparatus which includes the aerosol generator 31 will be described below.

As shown in FIG. 1, the film forming apparatus 30 includes the aerosol generator 31, an aerosol jetting nozzle 33 which jets aerosol generated in the aerosol generator 31 toward a body on which the film is formed (hereinafter, “film forming body”) 60, the film forming chamber 62 in which the aerosol jetting nozzle 33 and the film forming body 60 are arranged, and a controller 65 which controls the film forming apparatus 30.

The film forming chamber 62 includes a stage 61 for mounting the film forming body 60, the aerosol jetting nozzle 33 which is provided under the stage 61, and a stage driving mechanism 67 which changes a relative position of the stage 61 with respect to the aerosol jetting nozzle 33. Moreover, a vacuum pump 64 is connected to the film forming chamber 62 via a powder recovery unit 63, and it is possible to depressurize the interior of the film forming chamber 62 by a forced discharge by the vacuum pump 64. In other words, the film forming chamber 62 is formed as a depressurizing vessel.

The controller 65 is formed as a microprocessor with a CPU (central processing unit) as a main component, and includes in addition to the CPU, a ROM (read only memory) which stores computer programs for processing, a RAM (random access memory) which temporarily stores data, an input-output port, and a communication port.

Signals such as a pressure detection signal from a pressure detecting mechanism (not shown in the diagram) provided to the film forming chamber 62 and the aerosol generator 31 are input to the controller 65 via the input-output port. Moreover, the controller 65 carries out a control of the film forming apparatus 30 by executing a predetermined computer program stored in the ROM by the CPU, and upon receiving the input signals, by outputting, via the input-output port, a control signal to the flow controller 41, a control signal to the flow controller 36, a drive signal to the stage driving mechanism 67, and a drive signal to the vacuum pump 64.

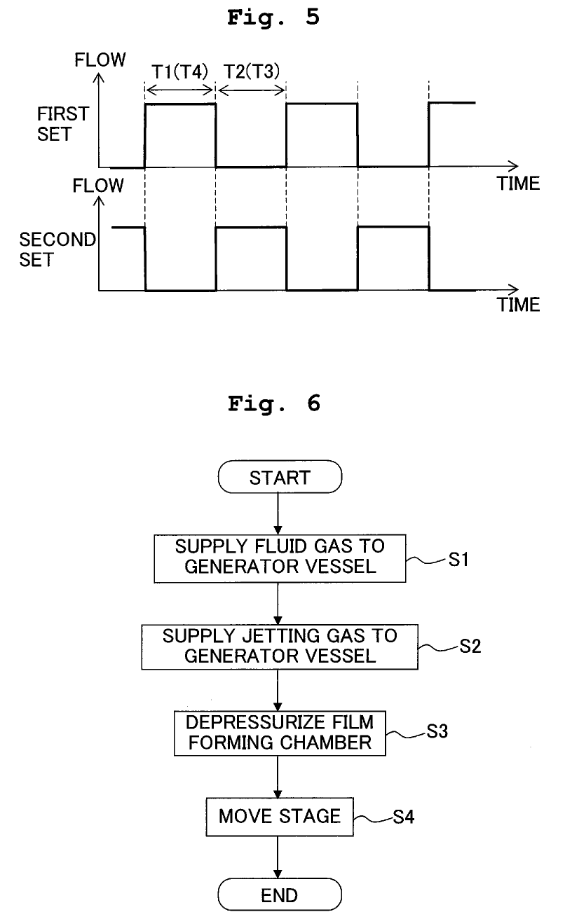

Here, a method for manufacturing the film forming body using the film forming apparatus 30 having the abovementioned structure will be described below. FIG. 6 is a flowchart for manufacturing the film forming body using the film forming apparatus 30.

The film forming body 60 is installed on the stage 61 of the film forming chamber 62, and the film forming chamber 62 is sealed in advance. In this state, firstly, aerosol is generated by the aerosol generator 31. Here, the controller 65 controls the flow controller 36 to operate such that a predetermined amount of the fluid gas is supplied to the fluid gas infusing chamber 56 of the aerosol generator 31 (step S01).

The fluid gas supplied to the fluid gas infusing chamber 56 passes from the fluid gas infusing chamber 56 through the porous plate 52, and is blown into the material powder accumulated at the bottom portion of the aerosol generation chamber 55 of the generator vessel 57. Accordingly, the material particles in the aerosol generation chamber 55 are blown up inside the aerosol generation chamber 55, and the material particles are dispersed in the fluid gas to generate aerosol. Moreover, by the fluid gas blown in the aerosol generation chamber 55 through the porous plate 52, the material powder accumulated on the bottom portion of the aerosol generation chamber 55 of the generator vessel 57 forms the fluid layer 54.

Simultaneously with the step S01, or with a slight delay, the controller 65 controls the flow controller 41 to operate such that a predetermined flow of the jetting gas is alternately supplied to the first-group jetting gas infusing tube 48 and the second-group jetting gas infusing tube 49 (step S02). Here, when the flow controller 41 is a rotary valve, by operating the rotary valve, the supply of the jetting gas is alternately switched to the first-group jetting gas infusing tube 48 and the second-group jetting gas infusing tube 49 after a predetermined time. However, the flow controller 41 is not restricted to a rotary valve, and by providing a valve body to each of the first-group jetting gas infusing tube 48 and the second-group jetting gas infusing tube 49, it is possible to let a structure such that the controller 65 controls these valve bodies to repeat alternately the opening and the closing of these valve bodies.

In such manner, by the jetting gas being supplied alternately to the first-group jetting gas infusing tube 48 and the second-group jetting gas infusing tube 49, the jetting gas is jetted continuously and alternately from the jetting ports 45a₁ belonging to the first group and the jetting ports 45a₂ belonging to the second group. By the high speed jetting gas blown into the material powder in the aerosol generator chamber 55 in such manner, the aggregate of the material particles is cracked, and the material particles are crushed, and moreover, the material powder which is accumulated (fluid layer 54) flows while being stirred.

Next, the controller 65 controls the vacuum pump 64 to depressurize the inside of the film forming chamber 62 down to a predetermined pressure (step S03). Accordingly, a pressure difference is developed between the inside of the aerosol generator 31 and the film forming chamber 62. Due to the pressure difference, the aerosol in the aerosol generator 31 is jetted from the aerosol jetting nozzle 33 while being accelerated by a high-velocity air current through the aerosol supply tube 32. In this manner, the material particles in the aerosol are jetted from the aerosol jetting nozzle 33 toward the film forming body 60, and are accumulated upon being collided at a high speed on the film forming body 60. Furthermore, the controller 65 controls the stage driving mechanism 67 to change appropriately the relative position of the stage 61 with respect to the aerosol jetting nozzle 33 while continuing the jetting of the aerosol from the aerosol jetting nozzle 33 to the film forming body 60 (step S04). Accordingly, a film formed of a composition of the material particles is formed over a desired range on the film forming body 60.

As it has been described above, in the aerosol generator 31 in the film forming, the fluid gas and the jetting gas are supplied together, and due to the effect of stirring the fluid layer 54, the effect of crushing the material particles, and the effect of cracking the aggregate of the material particles by the jetting gas, the aerosol is generated stably over a long period of time. Consequently, the concentration of the material particles in the aerosol jetted from the aerosol jetting nozzle 33 toward the film forming body 60 becomes substantially stable over a long period of time, and it is possible to carry out the film formation under stable film forming conditions. Accordingly, a thickness of the film generated on the film forming body 60 becomes uniform, and further, the film forming time becomes substantially constant, and it is possible to carry out stable film formation.

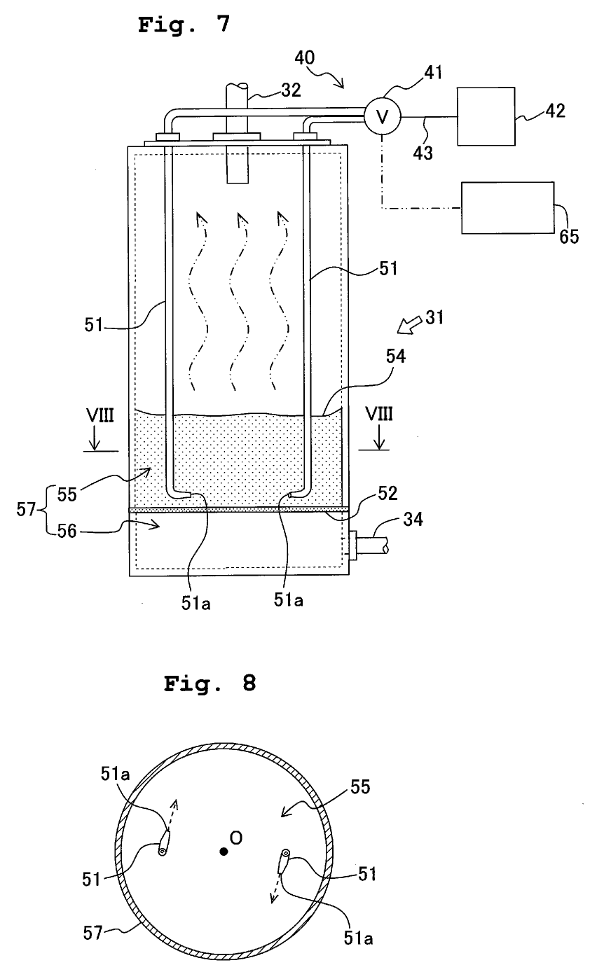

A second embodiment of the present invention will be described below by referring to FIG. 7 and FIG. 8. FIG. 7 is a side view of an aerosol generator according to the second embodiment, and FIG. 8 is a plan cross-sectional view of the aerosol generator according to the second embodiment. As shown in FIG. 7 and FIG. 8, the film forming apparatus 30 and the aerosol generator 31 according to the second embodiment, have the same structure as described in the first embodiment except for a nozzle provided to the aerosol generator 31, and a jetting port thereof. Consequently, the nozzle of the aerosol generator 31, and the jetting port thereof are described in detail in the following description, and the rest of the description which is same as in the first embodiment is omitted.

The aerosol generator 31 includes the generator vessel 57 having the circular cylindrical shape corresponding to the main body thereof, the jetting gas supply mechanism 40 which supplies jetting gas to a jetting port 45a which blows a gas such as air and nitrogen into the material powder accumulated inside the generator vessel 57, and the fluid gas supply mechanism 37 which supplies the fluid gas to the generator vessel.

The porous plate 52 is provided in the generator vessel 57 to divide the internal space thereof into two chambers namely an upper space and the lower space. The upper space divided by the porous plate 52 functions as the aerosol generation chamber 55 for generating aerosol in which the material particles are dispersed in the fluid gas. The aerosol supply tube 32 which supplies aerosol into the film forming chamber 62 of the film forming apparatus 30 which will be described later is connected to the ceiling surface of the aerosol generation chamber 55, in other words, to the ceiling surface of the generator vessel 57. The bottom surface of the aerosol generation chamber 55 is formed by the porous plate 52, and the powder is accommodated in the aerosol generation chamber 55 in the state of being accumulated on the porous plate 52. Furthermore, two jetting nozzles 51 are inserted through the ceiling surface of the generator vessel 57, and two jetting ports 51a opening at a lower end portion of the two jetting nozzles 51 are positioned in the material powder accumulated on the porous plate 52.

On the other hand, the lower space divided by the porous plate 52 functions as the fluid gas infusing chamber 56 for infusing the fluid gas into the generator vessel 57. The fluid gas supplied into the fluid gas infusing chamber 56 by the fluid gas supply mechanism 37 passes from the fluid gas infusing chamber 56 through fine holes of the porous plate 52, and is blown into the material particles accumulated on the bottom portion of the generator vessel 57. Accordingly, the material particles are blown up and float in the fluid gas, and the aerosol is generated.

The jetting gas supply mechanism 40 includes the jetting gas supply source 42, the jetting gas supply tube 43 which form the gas supply passage sending the jetting gas from the jetting gas supply source 42 to the jetting nozzles 51, and a flow controller 41 which is provided between the jetting gas supply tube 43 and the jetting nozzles 51.

The flow controller 41 is operated by a control of the controller 65, and functions as a flow controlling mechanism and a channel switching mechanism of the jetting gas which is sent from the jetting gas supply source 42 via the jetting gas supply tube 43. By the flow controller 41, it is possible to switch a state in which the jetting gas is not sent to any of the two jetting nozzles 51, a state in which the jetting gas is sent to only one jetting nozzle 51, and a state in which the jetting gas is sent only to the other jetting nozzle 51.

The two jetting ports 51a of the two jetting nozzles 51 are separated in a circumferential direction of an inner circumference of the generator vessel 57, and are arranged at an equiangular distance with a center O of the inner circumference of the generator vessel 57 as a center in a plan view. Moreover, a direction of jetting of a gas jetted from each jetting port 51a has a component in a circumferential direction with the center O of the inner circumference of the generator vessel 57 as a center.

The jetting gas is supplied intermittently to each jetting port 51a by the jetting gas supply mechanism 40, and is jetted intermittently at a high speed from the jetting port 51a into the material powder accumulated in the generator vessel 57. Here, the jetting gas is supplied to the two jetting ports 51a from the jetting gas supply mechanism 40 such that the jetting gas is jetted with different phases, and the jetting period does not overlap, and there is no period which is not a jetting period for any of the jetting ports 51a. In other words, the controller 65 controls the flow controller 41 to operate such that when the aerosol generator 31 is stopped, the jetting gas is not sent to any of the two jetting nozzles 51, and controls the flow controller 41 to operate such that when the aerosol generator 31 is in operation, the state is switched alternately to the state in which the jetting gas is sent to only one jetting nozzle 51, and the state in which the jetting gas is sent to only the other jetting nozzle 51. By making such an arrangement, as shown in FIG. 5, the jetting of the jetting gas from the one jetting port (first group) and the jetting of the jetting gas from the other jetting port (second group) is carried out alternately and continuously.

According to the structure described above, even in the aerosol generator 31 according to the second embodiment, similarly as in the aerosol generator 31 according to the first embodiment, by the jetting gas at a high speed being jetted intermittently into the material powder accumulated inside the generator vessel 57, the cracking the aggregate of the material particles and the stirring of the powder of the material particles is carried out effectively.

In the aerosol generator 31 described above, vibration mechanism which vibrates the aerosol generator 31 is not provided. However, the vibration mechanism may be provided. The flow amount of the fluid gas may be adjusted by the flow adjuster 36 constantly or changed periodically similar to the jetting gas.

What is claimed is:

1. An aerosol generator which generates aerosol by dispersing material particles in a carrier gas, comprising:
a generator vessel in which a powder of material particles is accommodated;
a jetting port which jets a jetting gas, in a direction having a component in a circumferential direction with a substantial center of an inner circumference of the generator vessel as a center of a circle, into the powder of the material particles accommodated and accumulated in the generator vessel;
a first gas supply mechanism which supplies the jetting gas to the jetting port; and
a controller which controls the first gas supply mechanism to adjust supply amount of the jetting gas supplied to the jetting port.

2. The aerosol generator according to claim 1, wherein the controller controls the first gas supply mechanism to supply the jetting gas intermittently to the jetting port.

3. The aerosol generator according to claim 1, wherein the jetting port is formed as a plurality of jetting ports, and the jetting ports are grouped into a plurality of port groups each including at least one jetting port; and
the controller controls the first gas supply mechanism to supply the jetting gas to each of the jetting ports, and to jet the jetting gas with a same phase from the jetting ports belonging to a group among the port groups, and to jet the jetting gas with different phases from jetting ports belonging to different groups respectively, among the port groups.

4. The aerosol generator according to claim 3, wherein the controller controls the first gas supply mechanism to supply the jetting gas to each of the jetting ports, and to jet the jetting gas such that at least a part of a jetting period of one group does not overlap with a jetting period of remaining groups among the plurality of port groups and that there is no period which is not a jetting period of any groups among the port groups.

5. The aerosol generator according to claim 3, wherein the controller controls the first gas supply mechanism to supply the jetting gas to each of the jetting ports, and to jet the jetting gas such that a total flow of the jetting gas jetted from the jetting ports belonging to a certain group among the port groups is same as a total flow of the jetting gas jetted from the jetting ports belonging to remaining groups among the port groups.

6. The aerosol generator according to claim 1, wherein the jetting port is an opening provided at a tip of a jetting nozzle; and
the first gas supply mechanism includes a gas supply source, a gas supply passage through which the jetting gas is fed from the gas supply source to the jetting nozzle, and a flow adjuster which is provided on the gas supply passage and which adjusts the supply amount of the jetting gas to be supplied to the jetting port.

7. The aerosol generator according to claim 1, wherein the jetting port is formed as a plurality of jetting ports, and the jetting ports are formed to be away from each other in a circumferential direction of an inner circumference of the generator vessel.

8. The aerosol generator according to claim 7, wherein the jetting ports are formed to be away from each other at an equiangular distance in the circumferential direction of the inner circumference of the generator vessel.

9. The aerosol generator according to claim 8, wherein the jetting ports are formed on an inner wall surface of the generator vessel.

10. The aerosol generator according to claim 9, wherein the generator vessel has a cylindrical shape and the jetting ports are formed at positions which are same distance from a bottom of the generator vessel.

11. The aerosol generator according to claim 10, wherein the positions at which the ports are formed are positioned lower than a height of the material particles accumulated in the generator vessel.

12. The aerosol generator according to claim 1, wherein the generator vessel includes a porous plate which divides an internal space of the generator vessel into an aerosol generation chamber accommodating the powder of the material particles and a fluid gas introducing chamber which is positioned below the aerosol generation chamber, and a second gas supply mechanism which supplies the fluid gas to the fluid gas infusing chamber.

13. A method for generating aerosol by dispersing material particles in a carrier gas by using the aerosol generator as defined in claim 1, the method comprising:
accommodating a powder of material particles in the generator vessel; and
jetting a jetting gas intermittently from the jetting port.

14. A film forming apparatus comprising:
the aerosol generator as defined in claim 1; and
a depressurizing vessel including a stage which holds a film forming body, and an aerosol jetting nozzle which jets aerosol generated in the aerosol generator onto the film forming body held by the stage, the stage and the aerosol jetting nozzle being arranged in the depressurizing vessel.

15. A method for manufacturing a film forming body by using the film forming apparatus as defined in claim 14, the method comprising:
generating aerosol in the aerosol generator;
introducing the aerosol into the depressurizing vessel; and
jetting the aerosol introduced into the depressurizing vessel from the aerosol jetting nozzle arranged in the depressurizing vessel onto the film forming body placed in the depressurizing vessel.
